(19) United States
(12) Patent Application Publication
(10) Pub. No.: US 2020/0391370 A1
(43) Pub. Date: Dec. 17, 2020

(54) Hand-Held Power Tool

(71) Applicant: Robert Bosch GmbH, Stuttgart (DE)

(72) Inventors: Peter Stierle, Pliezhausen (DE); Manfred Lutz, Filderstadt (DE); Juergen Wiker, Stuttgart (DE); Thomas Schomisch, Filderstadt (DE); Matthias Schneider, Stuttgart (DE)

(21) Appl. No.: 16/771,576

(22) PCT Filed: Dec. 10, 2018
(86) PCT No.: PCT/EP2018/084118

§ 371 Date: Jun. 10, 2020

(30) Foreign Application Priority Data
Dec. 12, 2017 (DE) 10 2017 222 525.4

(51) Int. Cl. B25F 5/02; H05K 5/02

(52) U.S. Cl. CPC B25F 5/02; H05K 5/0247; H05K 5/0217

(57) ABSTRACT

A hand-held power tool, in particular an angle grinder, includes a tool housing, which extends around a drive unit, an electronic unit for the open-loop and/or closed-loop control of the drive unit, and an electrical interface, around which the machine housing extends in at least one plane and which can be couplably connected to a communication unit. The machine housing has an access protection device, which is provided for protecting the interface from access, in particular, by a human finger and/or a test finger.

### PRIOR ART

EP 2 072 192 A 1 discloses an external control module for electric tools and/or electric appliances, having at least one interface by which the control module can be connected to a set of electronics of an electric tool. The interface in that case is realized in the form of electrically conductive pins that fit into through-holes of the housing of the electric tool. The through-holes have sealing elements.

The invention relates to a hand-held power tool according to the preamble of claim 1.

### DISCLOSURE OF THE INVENTION

The invention is based on the object of improving a hand-held power tool, in particular an angle grinder, by simple design measures.

The object is achieved with a hand-held power tool, in particular an angle grinder, comprising a power-tool housing that surrounds a drive unit, comprising an electronic unit for open-loop and/or closed-loop control of the drive unit, and comprising an electrical interface that can be couplably connected to a communication unit and that is surrounded by power-tool housing.

According to the invention, the power-tool housing has an access protection device that is designed to protect the interface from access, in particular by a human finger and/or a test finger.

The electronic unit may have an evaluation unit that is designed to influence and/or to store, for example, a motor performance characteristic and to transmit this, for example, to the communication unit. The electronic unit may have an open-loop and/or closed-loop control unit comprising, for example, a processor unit, and comprising a memory unit, and in particular comprising an operating program stored in the memory unit. The memory unit may be configured to store the data received from the drive unit.

The electrical interface may be realized to transmit data from the communication unit. The electrical interface may be designed to supply the communication unit with electrical energy.

The electrical interface may be surrounded, in at least one plane, by the power-tool housing.

The communication unit may have a further electrical interface that, in at least one operating state, can be contacted to the electrical interface of the electronic unit. Data can thereby be transmitted from the electronic unit to the communication unit and/or vice versa.

The communication unit may be realized to communicate with at least one external unit for the purpose of exchanging electronic data, at least for the purpose of open-loop and/or closed-loop control of the drive unit. The communication unit is preferably realized as a wireless communication unit. The communication unit in this case may be realized as a WLAN communication unit, as a Bluetooth communication unit, as a radio communication unit, as an RFID communication unit, as an NFC unit, as an infrared communication unit, as a mobile radio telephony network communication unit, or the like. Particularly preferably, the electronic unit is designed to control the drive unit, by open-loop and/or closed-loop control, in dependence on characteristic variable acquired by means of the communication unit and in dependence on electronic data transmitted to the electronic unit by means of the communication unit. Particularly preferably, the communication unit is designed for bidirectional data transmission. In an alternative design, the communication unit is realized as a communication unit connected, for example, by means of a data cable, such as, for example, a LAN communication unit, a USB communication unit, or the like. The external unit is preferably realized as a smartphone, which has an app for communicating with the communication unit. It is also conceivable, however, for the external unit to be realized as an external, transportable operating unit, as a fixedly installed operating unit at an operator's workplace, as a synchronization unit of a deployment location that is fixedly installed in a room and that can be controlled by a control centre, such as, for example, on the basis of company specifications/safety requirements, as a unit for monitoring characteristic variables of the body of an operator, as an external sensor unit, or as another operating unit, input station and/or centralized or decentralized terminal considered appropriate by persons skilled in the art. Thus, advantageously, synchronization of electronic data is made possible. If, for example, the hand-held power tool is put into operation in a synchronization mode, for example by insertion of an accumulator battery device, upon insertion of an electric power supply cable or by activation by an operator, a connection is established, at least partially automatically, between the communication unit and the external unit. Settings stored in the external unit can thus be transmitted, preferably directly, to the power tool. The settings in this case may be individual settings of an operator, such as, for example, a desired rapid acceleration to a set rotational speed and a maximum power, and/or company specifications such as, for example, compliance with a safety function in a defined area of a company premises or deployment location, etc.

If a cable-connected communication unit is used, the communication unit can be read-out or repaired, for example, particularly rapidly, in that the communication unit is connected to the external unit in a particularly advantageous manner.

“Designed” is to be understood to mean, in particular, specially programmed, specially configured and/or specially equipped. That an element and/or a unit are/is designed for a particular function, is to be understood to mean, in particular, that the element and/or the unit fulfill/fulfills and/or perform/performs this particular function in at least one application state and/or operating state.

A “drive unit” in this context is to be understood to mean, in particular, a unit designed to generate at least one driving torque and, for the purpose of transmission, to make it available, in particular, to an insert tool. Advantageously, the power tool comprises the drive unit. Particularly advantageously, the drive unit has at least one electric motor. Preferably, the drive unit is configured to drive and/or put into motion at least one insert tool of the power tool.

The power tool is preferably a hand-held, manually guided, manually operated and/or autonomously operating power tool that is realized as a non-stationary power tool and that is suitable, for example, for DIY-use. In principle, suitable power tools are a non-stationary power tool such as, for example, a hand-held circular saw according to the application DE 3740200 A1, or such as, for example, a knapsack brushcutter according to the application DE 19674764 A1. In addition, garden power tools, in particular lawn mowers, are suitable. Use with hand-held power tools, in particular power drills, power screwdrivers, power grinders or power cutting tools, is also possible.

The hand-held power tool may be mains-operated. The hand-held power tool may be mains-operated in that the hand-held power tool is connected to a mains electricity system by means of a mains power cable. The mains power supply cable in this case can receive electrical energy at a mains power socket such as, for example, a standard earthed plug, and transmit it to the hand tool. In an alternative embodiment, the hand-held power tool may be operated independently of a mains power supply. In this way, the operator of the hand-held power tool can be particularly protected against contact with a high-intensity current.

Normally, hand-guided electric tools are supplied with a mains voltage via the public mains electricity system. In contrast to electric tools with battery operation, the mains voltage can be applied to internal parts, hereinafter also referred to as electrical interface, such as, for example, metal parts and/or electrical conductors, which, if touched by the user, are discharged to earth via the operator, and endanger the operator. Consequently, these live internal parts must be protected against access by means of insulating housing parts.

These internal parts should not be touched by an operator of the hand-held power tool, such that an operator of the hand-held power tool is reliably protected by design measures against access to these parts.

These internal parts, or the electrical interface of the electronic unit, should preferably project into the hand-held power tool and be at a distance from the power-tool housing.

The dependent claims specify further expedient developments of the hand-held power tool according to the invention.

It may be expedient for the hand-held power tool to have a receiving unit that is designed to receive and support the communication unit. In a connected state, the receiving unit may form, at least portionally, a housing outer surface, in particular a housing outer-surface region, of the power-tool housing. The receiving unit may be designed to protect an operator from access to electrically conductive parts of the hand-held power tool and/or the communication unit. The receiving unit may be made from an electrically insulating material. The receiving unit may have a receiving region that is designed to receive and hold the communication unit. The receiving region may receive and hold the communication unit by means of a latching connection. The receiving region may be connected to the communication module in a materially bonded manner. The receiving region may have a coding element. The coding element may be designed to define the position of the communication unit, in at least one operating state, at or on the receiving unit. The receiving unit may be of an elongate design, and have a main extent that, in a connected state, is delimited by the housing outer surface region. The receiving unit may receive and support the communication unit in such a manner that the communication unit is surrounded, in at least one plane of 360°, by the receiving unit. The receiving unit is designed in such a manner that an operator of the hand-held power tool, when changing from a disconnected state to a connected state, is protected against contact with electrically conductive parts, or the electrical interface, of the hand-held power tool and/or of the communication unit. The outer surface of the housing may be arranged so as to be flush with the power-tool housing. This makes it particularly easy to integrate the receiving unit into the power-tool housing.

A connected state is to be understood to mean a state in which the communication unit is connected to the electrical interface by means of an electrical contact.

A disconnected state is to be understood to mean a state in which the communication unit is not in electrical contact with the electrical interface, and preferably not surrounded by the hand-held power tool, or the power-tool housing.

Further, it may be expedient for the power-tool housing to have a housing opening, and a guide recess that is at least partially delimited by the housing opening and that is designed to guide the receiving unit and/or the communication unit. The guide recess may have a rectangular cross section. The cross section may have a longitudinal extent that is at least two times, in particular at least three times, preferably at least four times, greater than a transverse extent realized transversely in relation to the longitudinal extent. The guide recess may be designed to receive the receiving unit and/or the communication unit in at least one operating state. The guide recess extends parallel to a main extent of the power-tool housing. The main extent of the power-tool housing may form a power-tool axis. The guide recess extends substantially parallel to a radial axis of the power-tool axis. The receiving unit can thereby be connected to the power-tool housing in a particularly simple and compact manner.

Furthermore, it may be expedient for the guide recess to have a cross section realized in such a manner that contact with the electrical interface by a human finger and/or a normative test finger is prevented. The guide recess may have a cross section that decreases, or reduces, at least portionally. The cross section may decrease in a direction from the outside to the inside of the power tool housing. The housing opening may have a cross section that is greater than a cross section of the guide recess. This prevents direct contact of a human finger with the interface.

Furthermore, it may be expedient for the hand-held power tool to have a cover element that is designed to cover the interface in at least one operating state. The cover element may have a flap element that covers the guide recess, at least partially, in at least one operating state. The cover element may be arranged in the guide recess. The cover element may be mounted so as to be swivelable about a swivel axis. The swivel axis may be arranged on a side of the guide recess that faces toward the electrical interface. The cover element may have a maximum cross section that is greater than the cross section of the guide recess. The flap element may be arranged on a side of the guide recess that faces away from the electrical interface. The cover element may be resiliently mounted about the swivel axis. The flap element may lie on a side of the guide recess that is opposite the swivel axis, and substantially conceal the guide recess.

It is proposed that the cover element be movably mounted with respect to the guide recess, and designed to cover the guide recess, at least portionally, in a disconnected state, and to expose it, not cover it, in a connected state. The cover element may be designed to cover the guide recess less in a connected state than in a disconnected state. The cover element may be resiliently mounted with respect to the power-tool housing by means of a swivel spring such as, for example, a leg spring. The spring element may be more preloaded in a connected state than in a disconnected state. Protection against reaching in can thereby be reduced in a particularly simple manner.

It is additionally proposed that the cover element may be movable, by means of the receiving unit and/or the communication unit, from a disconnected state into a connected state. The receiving unit and/or the communication unit in this case may swivel out the cover element. The cover element in this case may have a swivel recess designed to receive the receiving unit, at least partially. The receiving unit may be designed to engage in the swivel recess in such a manner that, upon a relative movement of the receiving unit relative to the cover element, the cover element is moved along a contour of the receiving unit, and the cover element is brought from a disconnected state into a connected state. This makes it particularly easy to achieve contact between the receiving unit and the access protection device, but also to avoid contamination in the power-tool housing.

It is further proposed that the hand-held power tool have a switch, in particular a microswitch, that is designed to electrically connect the interface to a mains electricity system in a connected state and to galvanically isolate it in a disconnected state, wherein the receiving unit has a button that is designed to actuate the switch in a connected state. The switch may be actuated by means of the receiving unit. This is a particularly simple way of preventing an operator from coming into contact with the interface, which is electrically live.

It is furthermore proposed that the communication unit be connected to the receiving unit in a form-locking and/or force-locking manner. The receiving unit may have an energy storage unit designed to store electrical energy and, in particular, to deliver it to the communication unit. The energy storage unit is to be realized, in particular, as an electrical cell that forms an electrochemical energy storage device and/or an energy converter. The energy storage unit may be realized as a battery such as, for example, a button cell. The energy storage unit may be of a rechargeable or non-rechargeable design.

It may be expedient for the receiving unit to have an unlocking element that is designed to move the cover element from a connected state into a disconnected state. The unlocking element may be realized as an unlocking contour. The unlocking element may be realized as an unlocking taper. The unlocking element may delimit the receiving unit. The unlocking element may be designed to reach into the swivel recess and swivel the cover element. In this way, access to the interface can be prevented even with relatively high amounts of force acting, for example, on an operator's finger, since the interface is concealed by the cover element.

Further, it may be expedient for the hand-held power tool to have a transmission unit that is designed to enable an optical connection between the communication unit and the electrical interface.

Furthermore, it may be expedient for the cover element to have a swivel recess that is designed, in an operating state, to receive a/the unlocking element, in order to move the cover element from a disconnected state into a connected state. The unlocking element of the receiving unit can thereby engage under the cover element in order to fold open the cover element.

A further aspect of the invention is a system having a hand-held power tool, comprising an electronic unit that has an electrical interface, and comprising a communication unit that is coupled to the electrical interface.

### BRIEF DESCRIPTION OF THE DRAWINGS

Further advantages are given by the following description of the drawing. The drawing shows exemplary embodiments of the invention. The drawings, the description and the claims contain numerous features in combination. Persons skilled in the art will expediently also consider the features individually, and combine them to form appropriate further combinations. There are shown:

FIG. 1 a perspective view of a first embodiment of a hand-held power tool according to the invention,

FIG. 2 a further view of the hand-held power tool from FIG. 1,

FIG. 3 a schematic section through the hand-held power tool,

FIG. 4 a view of a receiving unit,

FIG. 5 a further view of the receiving unit,

FIG. 6 a view of the hand-held power tool,

FIG. 7 a view of a second embodiment of the hand-held power tool,

FIG. 8 a further view of the second embodiment of the hand-held power tool,

FIG. 9 a section through the hand-held power tool from FIG. 8,

FIG. 10 a section of the receiving unit from FIG. 5,

FIG. 11 a section through the hand-held power tool from FIG. 1,

FIG. 12 a section through the hand-held power tool from FIG. 1,

FIG. 13 a section through the hand-held power tool from FIG. 1, and

FIG. 14 a view of a part of the hand-held power tool from FIG. 1.

In the following figures, components that are the same are denoted by the same references.

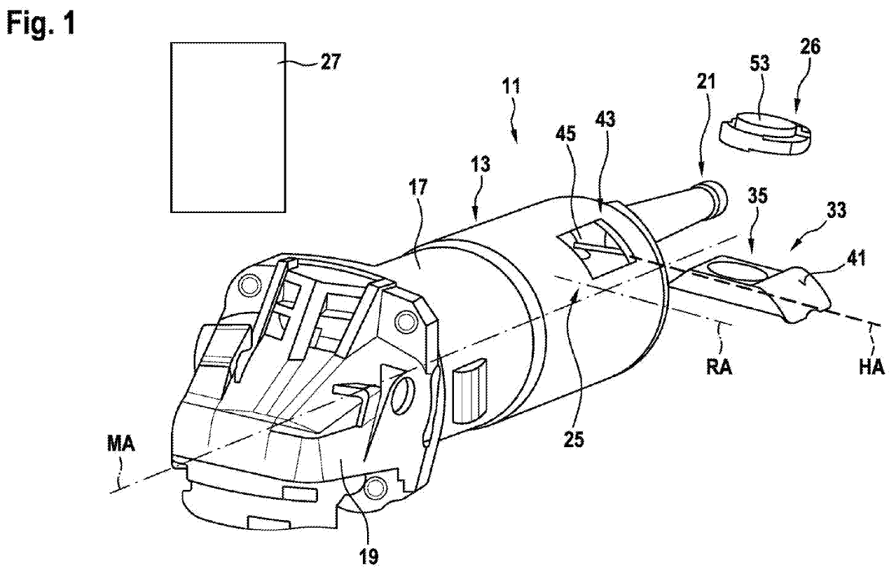

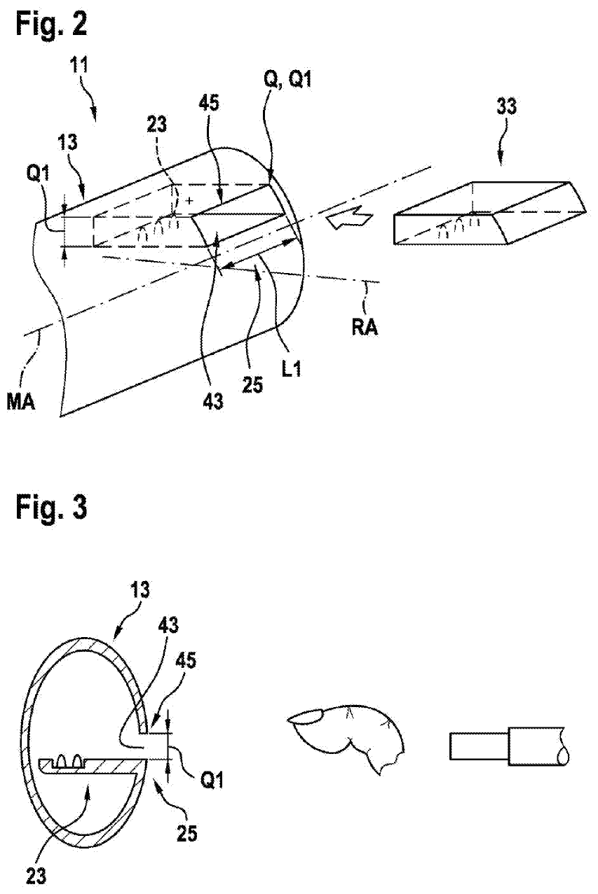

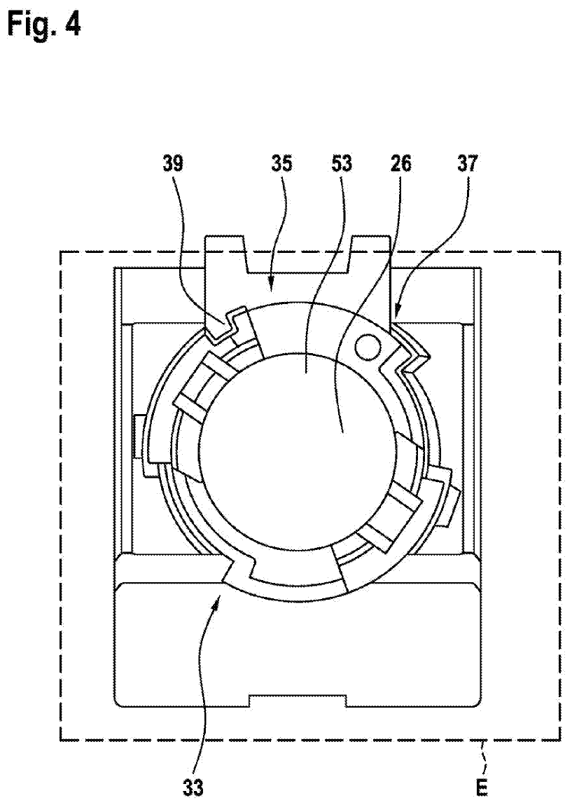

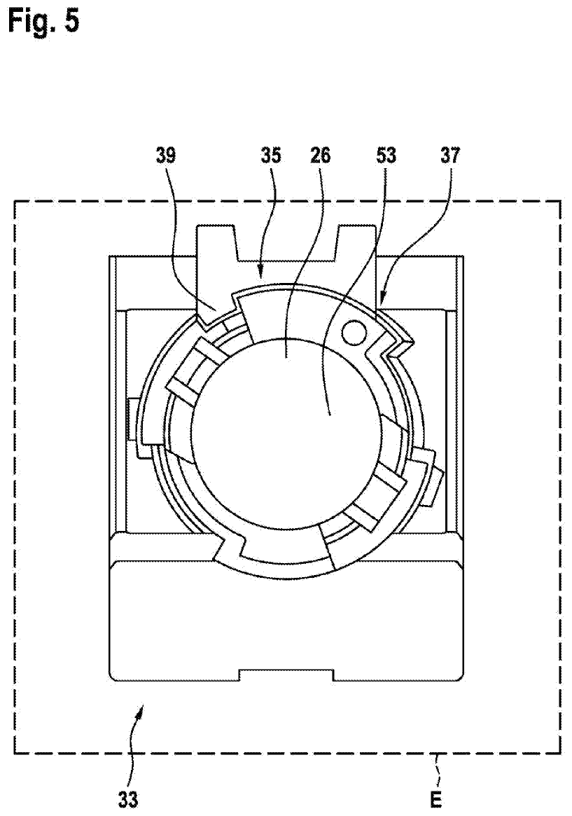

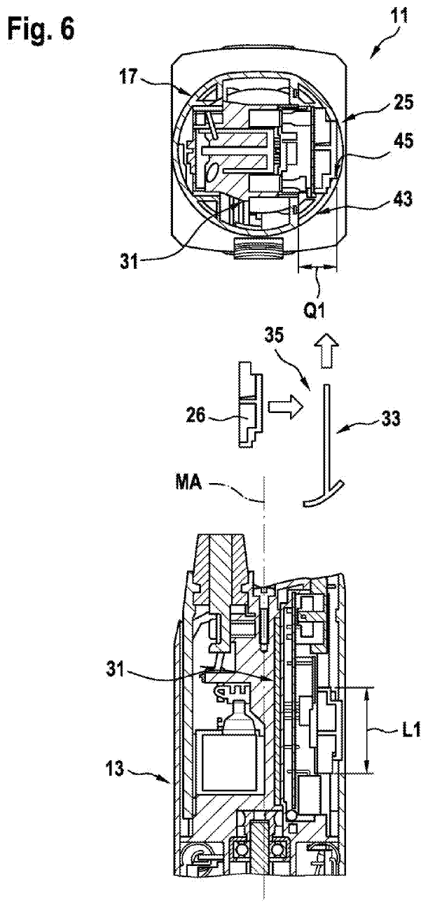

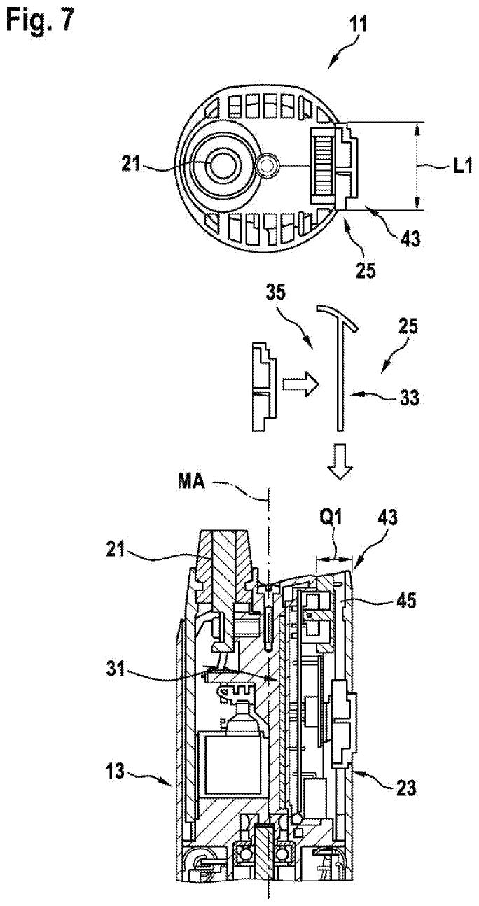

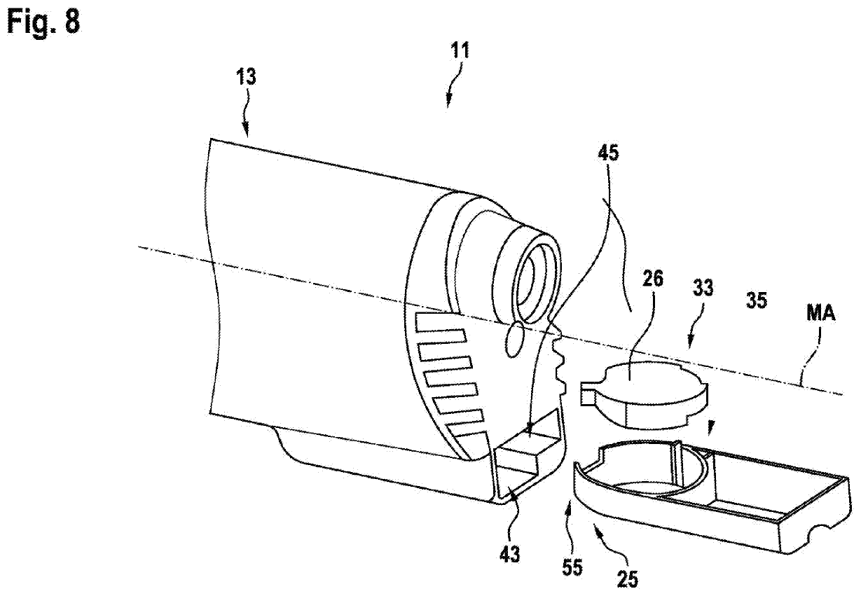

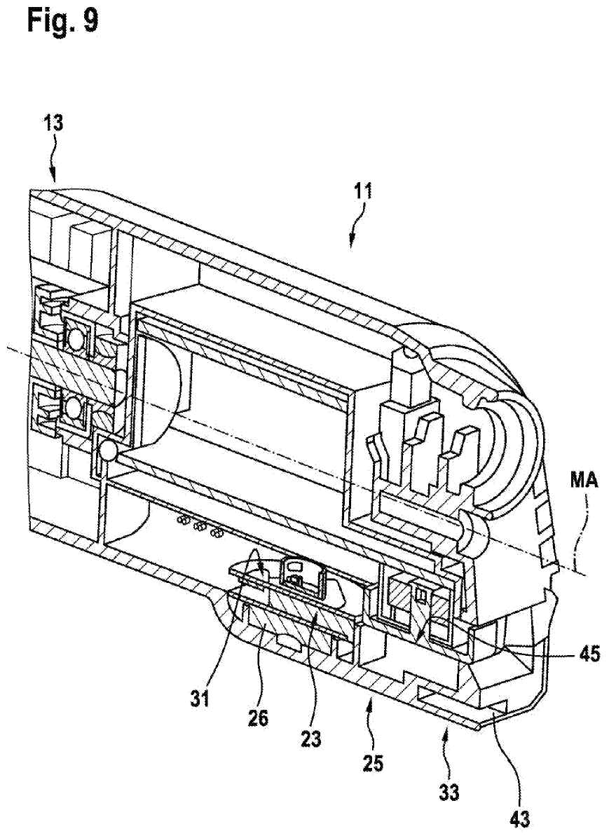

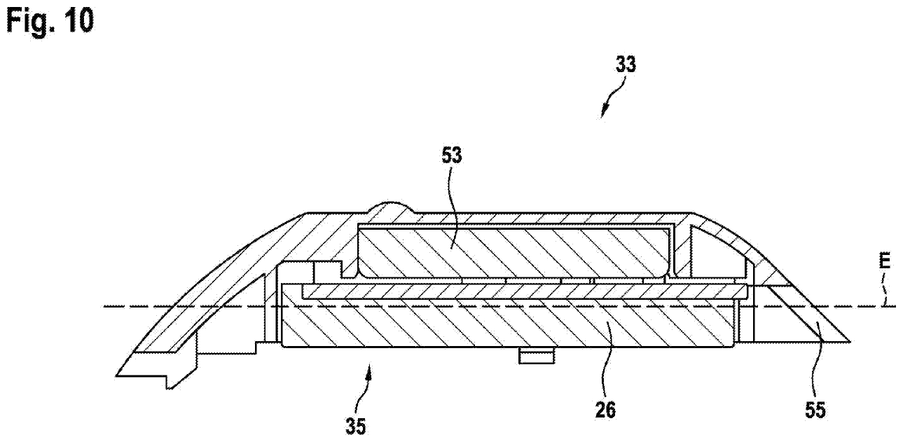

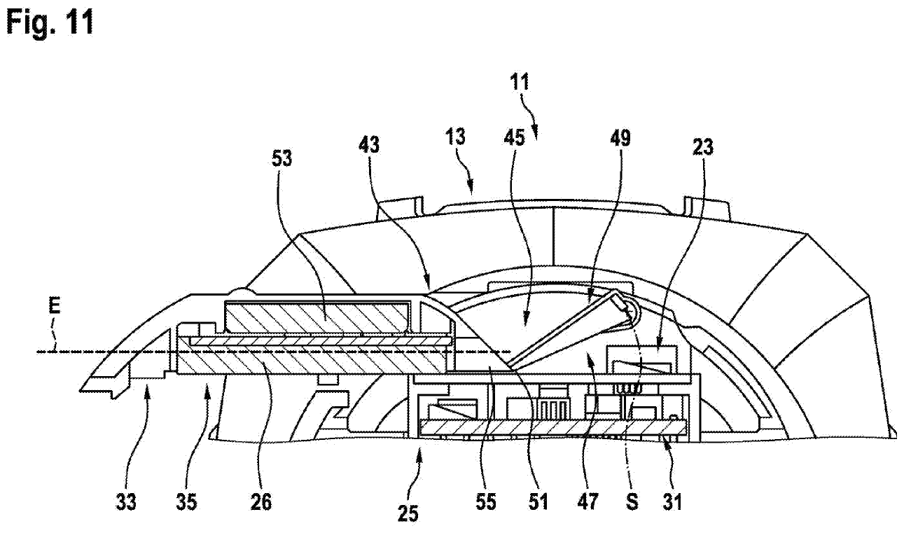

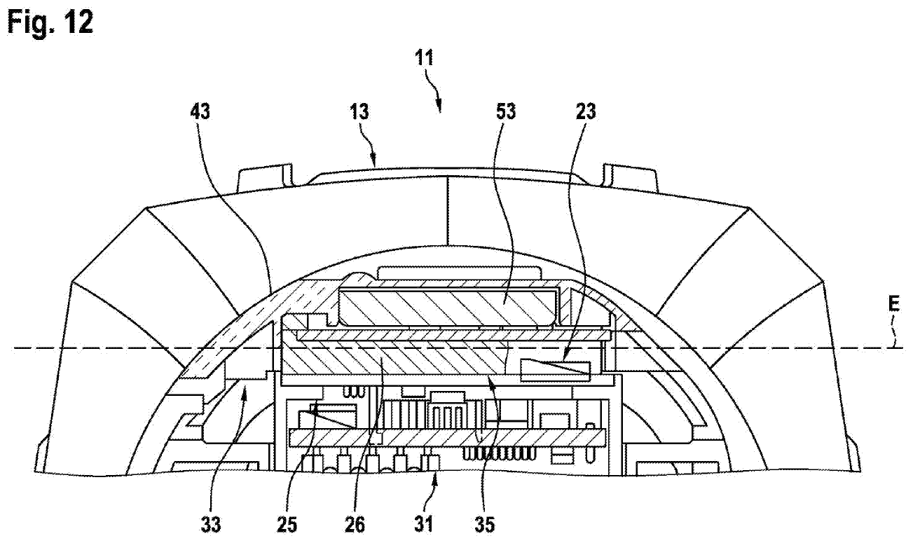

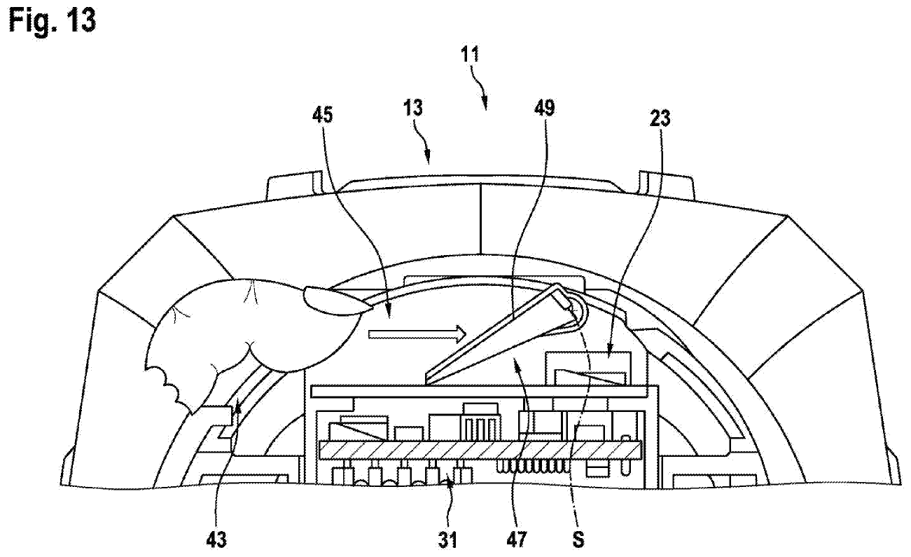

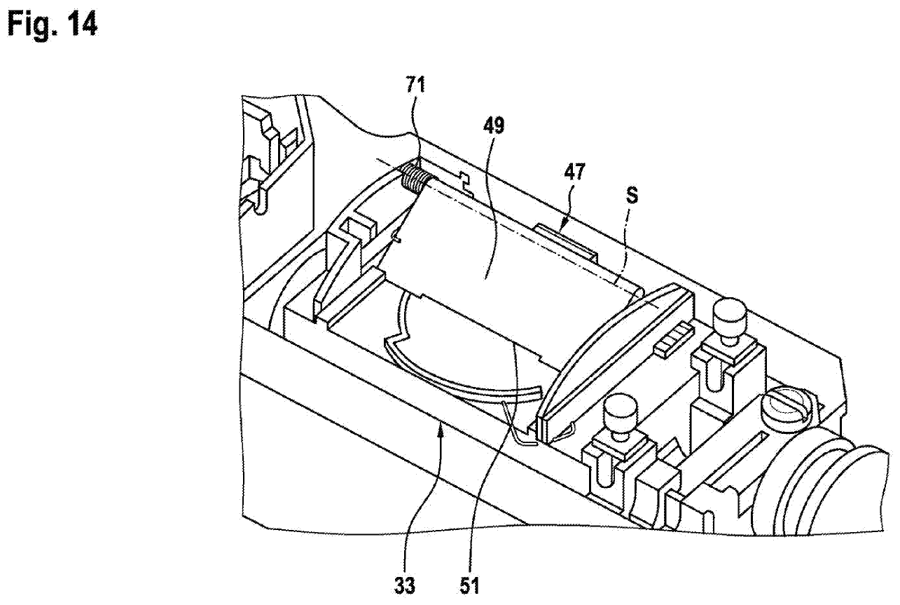

FIG. 1 shows a mains-operate hand-held power tool 11. The hand-held power tool 11 in this case is realized as an angle grinder. The hand-held power tool 11 can be coupled to an accessory device realized as a protective hood (not shown). The hand-held power tool 11 additionally comprises at least one power-tool housing 13 and a main handle 15, which extends, on a side of the power tool 13 that faces away from an insert tool (not shown), in the direction of main extent H of the hand-held power tool 11. The insert tool is held on the hand-held power tool 11 by means of a tool receiver.

The insert tool is not shown, but is usually realized as a grinding or cutting disk. The power-tool housing 13 comprises a motor housing 17 for receiving a drive unit of the hand-held power tool 11. The power-tool housing 13 additionally comprises a transmission housing 19 for receiving an output unit of the hand-held power tool 11. The power-tool housing 13 surrounds the drive unit. The drive unit is designed to drive the insert tool in rotation, via the output unit. The drive unit has an electric motor.

A further accessory device, realized as an ancillary handle unit, that extends transversely in relation to the direction of main extent H of the hand-held power tool 11, may be arranged on the transmission housing 19.

The hand-held power tool 11 preferably comprises a mains-operated energy supply device 21 that has an earthed plug, or other plug considered to be appropriate. Alternatively or additionally, the hand-held power tool 11 may be able to be operated independently of a mains power operation, by means of an accumulator battery pack. The energy supply device 21 has a mains power cable by which it is connected to the mains electricity system. The mains power cable in this case can receive electrical energy by means of a standard earthed plug, and transmit it to the hand-held power tool 11. In an alternative design, the hand-held power tool may be operated independently of a mains power supply. In this way, the operator of the hand-held power tool 11 can be particularly protected against contact with a high-intensity current.

The hand-held power tool 11 is realized as an angle grinder. The hand-held power tool 11 has an electronic unit 31 for open-loop and/or closed-loop control of the drive unit. The hand-held power tool 11 has an electrical interface 23 that can be couplably connected to a communication unit 26 and that is surrounded, in at least one plane E, by the power-tool housing 13.

According to the invention, the power-tool housing 13 has an access protection device 25 that is designed to protect the interface 23 from access by a human finger and/or a test finger.

The electrical interface 23 is realized to transmit electronic data from the communication unit 26. The electrical interface 23 may be designed to supply the communication unit 26 with electrical energy.

The communication unit 26 has a further electrical interface 23 that contacts the electrical interface 23 of the electronic unit 31 in a connected state. Data can thereby be transmitted from the electronic unit 31 to the communication unit 26 and/or vice versa.

The communication unit 26 may be realized to communicate with at least one external unit 27 for the purpose of exchanging electronic data, at least for the purpose of controlling the drive unit by open-loop and/or closed-loop control. The communication unit 26 is realized as a wireless communication unit 26. The communication unit 26 is realized as a Bluetooth communication unit 26. The electronic unit 31 is designed to control the drive unit, by open-loop and/or closed-loop control, in dependence on characteristic variable acquired by means of the communication unit 26 and in dependence on electronic data transmitted to the electronic unit 31 by means of the communication unit 26. A bidirectional transmission of data may be provided in this case.

The hand-held power tool 11 has a receiving unit 33 that is designed to receive and support the communication unit 26. In a connected state, the receiving unit 33 forms, at least portionally, a housing outer surface region 41 of the power-tool housing 13. The receiving unit 33 is designed to protect an operator from access to electrically conductive parts, or the interface 23 of the hand-held power tool 11 and/or of the communication unit 26. The receiving unit 33 is made from an electrically insulating material. The receiving unit 33 has a receiving region 35 that is designed to receive and hold the communication unit 26. The receiving unit 33 receives the communication unit 26 by means of a latching connection or by means of a clamping connection or by means of a bayonet connection 37, and holds the communication unit 26 on the receiving unit 33. Alternatively or additionally, the receiving region 35 may be materially bonded to the communication unit 26. The receiving region 35 has a coding element 39. The coding element 39 is designed to define the position of the communication unit 26, in at least one operating state, at or on the receiving unit 33. The receiving unit 33 is of an elongate design, and has a main extent HA that, in a connected state, is delimited by the housing outer surface region 41. The receiving unit 33 receives and the communication unit 26 in such a manner that the communication unit 26 is surrounded, in at least one plane E of 360°, by the receiving unit 33. In a connected state, the housing outer surface region 41 is arranged so as to be flush with the power-tool housing 13.

The power-tool housing 13 has a housing opening 43, and a guide recess 45 that is at least partially delimited by the housing opening 43 and that is designed to guide the receiving unit 33 and/or the communication unit 26. The guide recess 45 has a rectangular outer cross section Q. The cross section Q has a longitudinal extent L1 that is at least two times greater than a transverse extent Q1 realized transversely in relation to the longitudinal extent L1. The guide recess 45 is designed to receive the receiving unit 33 and/or the communication unit 26 in at least one operating state. The guide recess 45 extends parallel to a main extent H of the power-tool housing 13. The main extent H of the power-tool housing 13 forms a power-tool axis MA. The guide recess 45 extends substantially parallel to a radial axis RA of the power-tool axis MA.

The receiving unit 33 is realized in the manner of a drawer, and is designed to be pushed into the guide recess 45.

The guide recess 45 has a cross section Q1 realized in such a manner that contact with the electrical interface 23 by a human finger and/or a normative test finger is prevented. The guide recess 45 may have a cross section Q1 that decreases, or reduces, at least portionally. The cross section Q1 decreases in a direction from the outside to the inside of the power-tool housing 13. The housing opening 43 has a cross section that is greater than a cross section of the guide recess 45.

The hand-held power tool 11 has a cover element 47 that is designed to cover the interface 23 in at least one operating state. The cover element 47 has a flap element 49 that covers the guide recess 45, at least partially, in at least one operating state. The cover element 47 is mounted so as to be swivelable about a swivel axis S. The swivel axis S is arranged on a side of the guide recess 45 that faces toward the electrical interface 23. The flap element 49 has a maximum cross section that is greater than the cross section of the guide recess 45. In an alternative embodiment, the flap element 49 may have a maximum cross section that is less than the cross section of the guide recess 45. The flap element 49 is arranged on a side of the guide recess 45 that faces away from the interface 23. The cover element 47 is resiliently mounted about the swivel axis S. The flap element 49 lies on a side of the guide recess 45 that is opposite the swivel axis S, and substantially conceals the guide recess 45 in a disconnected state.

The cover element 47 is movably mounted with respect to the guide recess 45. The cover element 47 is designed substantially to cover the guide recess 45 in a disconnected state. The cover element 47 is designed to cover the guide recess 45 less in a connected state than in a disconnected state. The cover element 47 is resiliently mounted with respect to the power-tool housing by means of a leg spring. The spring element 71 is more preloaded in a connected state than in a disconnected state.

The cover element 47 is movable, by means of the receiving unit 33 and/or the communication unit 26, from a disconnected state into a connected state. The receiving unit 33 in this case may swivel out the cover element 47. The cover element 47 has a swivel recess 51 (FIG. 14) designed to receive the receiving unit 33, at least partially. The receiving unit 33 is designed to engage in the swivel recess 51 in such a manner that, upon a relative movement of the receiving unit 33 relative to the cover element 47, the cover element 47 is moved along a contour of the receiving unit 33, and the cover element 47 is brought from a disconnected state into a connected state.

The communication unit 26 is connected to the receiving unit 33 in a form-locking and/or force locking manner. The receiving unit 33 has an energy storage unit 53 designed to store electrical energy, and to deliver it to the communication unit 26. The energy storage unit 53 is realized such that it can be coupled to the receiving unit 33. The energy storage unit 53 is designed to be with electrically coupled to the communication unit 26. The energy storage unit 53 is realized as a battery such as, for example, a button cell.

The receiving unit 33 has an unlocking element 55 that is designed to move the cover element 47 from a connected state into a disconnected state. The unlocking element 55 is realized as an unlocking contour. The unlocking element 55 is realized as an unlocking taper. The unlocking element 55 delimits the receiving unit 33. The unlocking element 55 is designed to reach into the swivel recess 51 and swivel the cover element 47.

The swivel recess 51 is designed, in an operating state, to receive a/the unlocking element 55 in order to move the cover element 47 from a disconnected state into a connected state. The unlocking element 55 of the receiving unit 33 in this case engages under the cover element 47, in order to move the cover element 47 into the connected state.

The hand-held power tool 11 has an optical transmission unit that is designed to enable an optical connection between the communication unit 26 and the electrical interface 23.

1. A mains-operated hand-held power tool, comprising:
a drive unit;
a power-tool housing surrounding the drive unit;
an electronic unit operatively connected to the drive unit and configured for open-loop and/or closed-loop control of the drive unit;
a communication unit; and
an electrical interface configured to be couplably connected to the communication unit, and surrounded by the power-tool housing,
wherein the power-tool housing has an access protection device configured to protect the electrical interface from access.

2. The hand-held power tool as claimed in claim 1, further comprising:
a receiving unit configured to receive and to support the communication unit,
wherein, in a connected state, the receiving unit forms, at least portionally, a housing outer surface of the power-tool housing.

3. The hand-held power tool as claimed in claim 2, wherein the power-tool housing has a housing opening and a guide recess that is at least partially delimited by the housing opening and that is configured to guide the receiving unit and/or the communication unit.

4. The hand-held power tool as claimed in claim 3, wherein the guide recess has a cross section configured such manner that contact with the electrical interface by a human finger and/or a normative test finger is prevented.

5. The hand-held power tool as claimed in claim 3, further comprising:
a cover element that is configured to cover the electrical interface in at least one operating state.

6. The hand-held power tool as claimed in claim 5, wherein the cover element is movably mounted with respect to the guide recess, and configured to cover the guide recess, at least portionally, in a disconnected state, and to expose the guide recess in a connected state.

7. The hand-held power tool as claimed in claim 5, wherein the cover element is movable, by the receiving unit and/or the communication unit, from a disconnected state into a connected state.

8. The hand-held power tool as claimed in claim 2, further comprising:
a switch configured to electrically connect the electrical interface to a mains electricity system in a connected state and to galvanically isolate the electrical interface it in a disconnected state,
wherein the receiving unit has a button that is configured to actuate the switch in the connected state.

9. The hand-held power tool as claimed in claim 2, wherein the communication unit is connected to the receiving unit in a form-locking and/or force-locking manner.

10. The hand-held power tool as claimed in claim 5, wherein the receiving unit has an unlocking element that is configured to move the cover element from a connected state into a disconnected state.

11. The hand-held power tool as claimed in claim 1, further comprising:
a transmission unit configured to enable an optical connection between the communication unit and the electrical interface.

12. The hand-held power tool as claimed in claim 10, wherein the cover element has a swivel recess that is configured, in an operating state, to receive the unlocking element, in order to move the cover element from the disconnected state into the connected state.

13. The hand-held power tool as claimed in claim 1, wherein the access protection device protects the electrical interface from access by a human finger and/or a test finger.
